(19) United States
(12) Patent Application Publication
(10) Pub. No.: US 2013/0098421 A1
(43) Pub. Date: Apr. 25, 2013

(54) FLEXIBLE SOLAR BATTERY MODULE AND RELATED MANUFACTURING METHOD

(71) Applicants: Shih-Wei Lee, Kaohsiung City (TW); Yao-Tsang Tsai, Tainan City (TW); Ming-Hung Lin, Pingtung County (TW)

(72) Inventors: Shih-Wei Lee, Kaohsiung City (TW); Yao-Tsang Tsai, Tainan City (TW); Ming-Hung Lin, Pingtung County (TW)

(21) Appl. No.: 13/448,415

(22) Filed: Apr. 17, 2012

(30) Foreign Application Priority Data
Oct. 25, 2011 (TW) 100138618

(51) Int. Cl. H01L 31/05; H01L 31/18

(52) U.S. Cl. 136/244; 438/67; 257/E31.11; 257/E31.124

(57) ABSTRACT

A flexible solar battery module includes a flexible insulating base and a plurality of solar batteries separately disposed on the flexible insulating base. The solar battery includes a substrate disposed on the flexible insulating base, a first electrode disposed on the substrate, a photoelectric transducing layer disposed on the first electrode and exposing parts of the first electrode, and a second electrode disposed on the photoelectric transducing layer. The flexible solar battery module further includes an insulating layer disposed on the exposed first electrode of each solar battery and the exposed flexible insulating base between the adjacent solar batteries, and an auxiliary electrode disposed on the second electrode of each solar battery and the exposed first electrode of the adjacent solar battery for setting the plurality of solar batteries in a series connection.

### BACKGROUND OF THE INVENTION

1. Field of the Invention

The present invention relates to a solar battery module, and more particularly, to a flexible solar battery module and a related manufacturing method.

2. Description of the Prior Art

Conventional flexible solar battery module includes a base and a plurality of solar batteries, and the base is a metal foil whereon the solar battery is formed. The electrode of each solar battery stretches to the metal base of the adjacent solar battery, so as to set the plurality of solar batteries in a series connection. Drawbacks of the conventional flexible solar battery module is that an upper electrode and a photoelectric transducing layer of each solar battery may be broken easily due to pressure generated by the curved metal base, and photoelectric transducing efficiency of the conventional flexible solar battery module is decreased accordingly, which is disclosed in US patent 2010/0282288.

In addition, a method of utilizing insulating adhesive and conductive layers to set the plurality of solar batteries in a series connection is disclosed in U.S. Pat. No. 7,932,124 and US application 2007/0079866. A conventional flexible solar battery module that includes a plurality of solar batteries separately disposed on a flexible insulating base is further disclosed in US application 2008/0196756. In US application 2008/0196756, an insulating layer is disposed between the adjacent solar batteries for preventing short, and two ends of a conductive electrode are respectively formed on the upper electrode and the low electrode of the adjacent solar batteries for setting the plurality of solar batteries in the series connection. Procedures disclosed in the known US patents are complicated, a series of cutting processes is necessary for isolating the adjacent solar batteries for preventing the short. Therefore, design of a flexible solar battery module with easy manufacturing procedures is an important issue in the solar battery industry.

### SUMMARY OF THE INVENTION

The present invention provides a flexible solar battery module and a related manufacturing method for solving above drawbacks.

According to the claimed invention, a method of setting a plurality of solar batteries in a series connection to be a flexible solar battery module is disclosed. The solar battery includes a substrate, a first electrode, a photoelectric transducing layer and a second electrode. The method includes executing a cutting procedure to the plurality of solar batteries, so as to remove parts of the second electrode and the photoelectric transducing layer of at least one edge of each solar battery for exposing a part of the first electrode; disposing the plurality of solar batteries separately on a flexible insulating base to expose a part of the flexible insulating base; forming an insulating layer between the adjacent solar batteries and on the part of the flexible insulating base; and forming an auxiliary electrode on the second electrode of each solar battery and the part of the exposed first electrode of the adjacent solar battery for setting the plurality of solar batteries in the series connection.

According to the claimed invention, a flexible solar battery module includes a flexible insulating base and a plurality of solar batteries separately disposed on the flexible insulating base. Each solar battery includes a substrate disposed on the flexible insulating base, a first electrode formed on the substrate, a photoelectric transducing layer formed on a surface of the first electrode for exposing a part of the first electrode, and a second electrode formed on the photoelectric transducing layer. A width of the photoelectric transducing layer is smaller than a width of the first electrode. The flexible solar battery module includes an insulating layer formed on the part of the exposed first electrode of each solar battery and the part of the exposed flexible insulating base of the adjacent solar battery, and an auxiliary electrode formed on the second electrode of each solar battery and the part of the exposed first electrode of the adjacent solar battery for setting the plurality of solar batteries in a series connection.

The present invention could dispose the plurality of solar batteries separately on the flexible insulating base, and form the insulating layer between the adjacent solar batteries for preventing the short. The present invention could further utilize the auxiliary electrode to connect the adjacent solar batteries for forming the flexible solar battery module. In addition, the present invention has advantages of easy manufacturing procedures, so that the present invention could manufacture the flexible solar battery module with preferable manufacturing quality and preferred photoelectric transducing efficiency.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a sectional view of a flexible solar battery module according to an embodiment of the present invention.

FIG. 2 is a top view of the flexible solar battery module according to the embodiment of the present invention.

FIG. 3 is a flow chart of a method of manufacturing the flexible solar battery module according to the embodiment of the present invention.

FIG. 4 to FIG. 7 are sectional views of the flexible solar battery module in different procedures according to the embodiment of the present invention.

FIG. 8 is a flow chart of a method of manufacturing the flexible solar battery module according to the other embodiment of the present invention.

FIG. 9 to FIG. 11 are sectional views of the flexible solar battery module in different procedures according to the other embodiment of the present invention.

### DETAILED DESCRIPTION

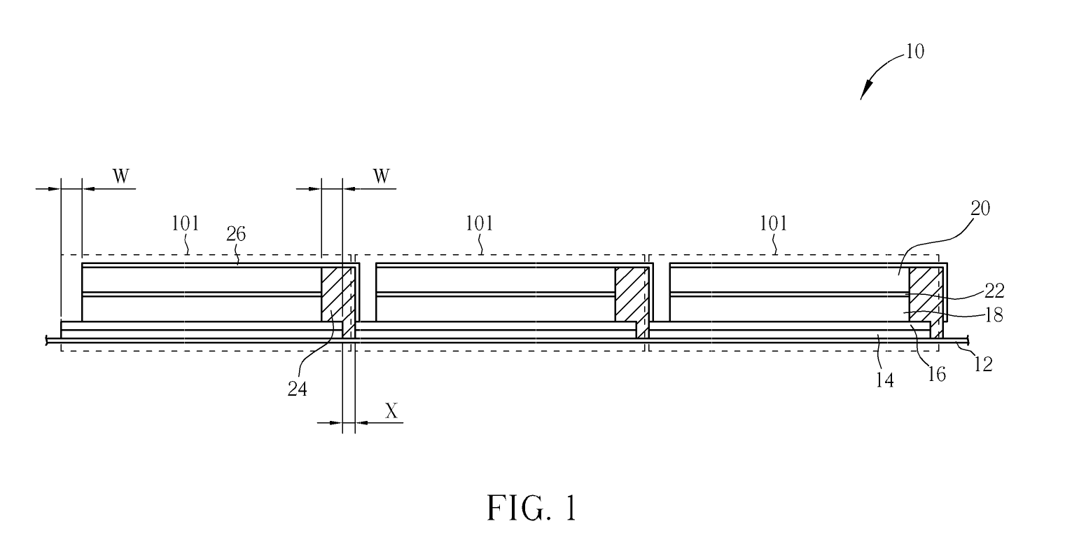

Please refer to FIG. 1. FIG. 1 is a sectional view of a flexible solar battery module 10 according to an embodiment of the present invention. The flexible solar battery module 10 includes a flexible insulating base 12 and a plurality of solar batteries 101. The flexible insulating base 12 could be a metal foil capable of being bent by pressure, and the plurality of solar batteries 101 could be separately disposed on the flexible insulating base 12. The flexible insulating base 12 could be made of insulating material, such as ethylene vinyl acetate (EVA) material or polyimide (PI) material. The solar battery 101 could be a conventional simple solar battery. Each solar battery 101 includes a substrate 14 disposed on the flexible insulating base 12, a first electrode 16 formed on the substrate 14, a photoelectric transducing layer 18 formed on a surface of the first electrode 16, and a second electrode 20 formed on the photoelectric transducing layer 18. A width of the photoelectric transducing layer 18 could be smaller than a width of the first electrode 16, and a part of the first electrode 16 could be exposed on two edges of the photoelectric transducing layer 18. A width of the second electrode 20 could be equal to the width of the photoelectric transducing layer 18. Each solar battery 101 could further include a buffer layer 22 formed between the photoelectric transducing layer 18 and the second electrode 20.

The flexible solar battery module 10 further includes a plurality of insulating layers 24 formed on the part of the exposed first electrode 16 of each solar battery 101, and on the part of the exposed flexible insulating base 12 between the adjacent solar batteries 101. The first electrode 16 and the second electrode 20 of the corresponding solar battery 101 could be isolated from the first electrode 16 of the adjacent solar battery 101 by the insulating layer 24, so as to prevent the adjacent solar batteries 101 from short. The flexible solar battery module 10 further includes a plurality of auxiliary electrodes 26 formed on the second electrode 20 of each solar battery 101, and on the part of the exposed first electrode 16 of the adjacent solar battery 101. Each auxiliary electrode 26 is formed across the corresponding insulating layer 24, so that two ends of the auxiliary electrode 26 could respectively contact the second electrode 20 of the corresponding solar battery 101 and the first electrode 16 of the adjacent solar battery 101, and the plurality of solar batteries 101 disposed on the flexible insulating base 12 could be set in a series connection.

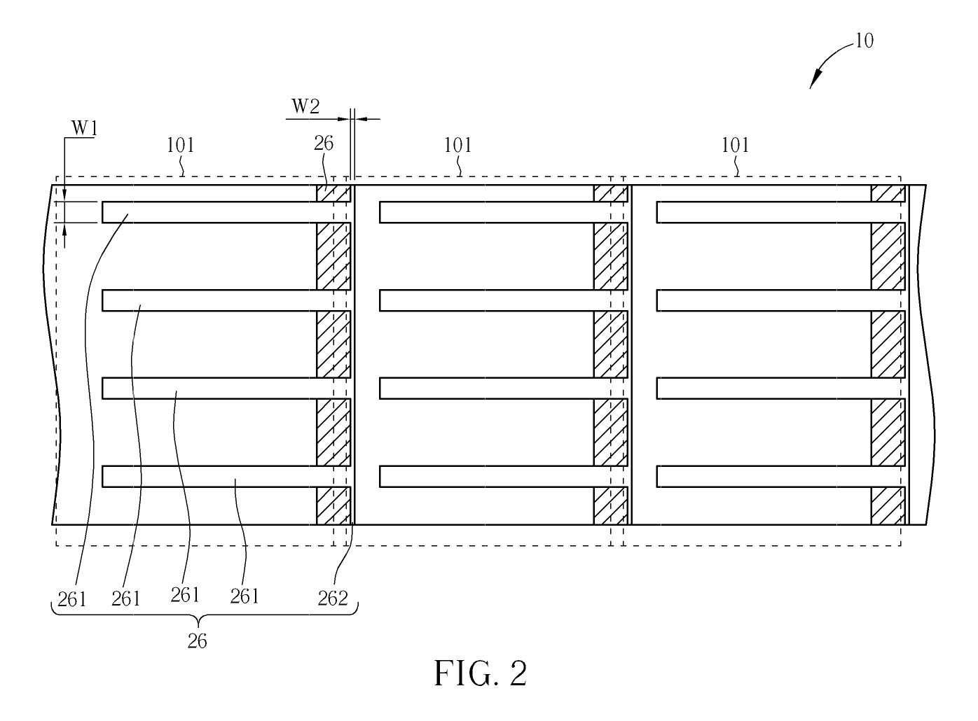

Please refer to FIG. 2. FIG. 2 is a top view of the flexible solar battery module 10 according to the embodiment of the present invention. The auxiliary electrode 26 could include a plurality of first parts 261 and a second part 262. An end of each first part 261 could be connected to the second part 262, and the other end of the first part 261 stretches on the second electrode 20 in reverse, which means that the auxiliary electrode 26 could be a bus bar structure. As shown in FIG. 2, the plurality of first parts 261 could be respectively disposed on the insulating layer 26 and the second electrode 20 of the corresponding solar battery 101, and the second part 262 could be disposed on the part of the exposed first electrode 16 of the adjacent solar battery 101, so that the auxiliary electrode 26 is utilized to set the adjacent solar batteries 101 in the series connection for forming the flexible solar battery module 10. As shown in FIG. 1 and FIG. 2, a width of the exposed first electrode 16 of each solar battery 101 could be W, a distance of the exposed flexible insulating base 12 between the adjacent solar batteries 101 separately disposed on the flexible insulating base 12 is X, a width of the first part 261 of the auxiliary electrode 26 is W1, and a width of the second part 262 of the auxiliary electrode 26 is W2. The width W2 is smaller than the width W for ensuring that the adjacent solar batteries 101 are open.

Generally, the substrate 14 could be the metal foil, such as a stainless steel foil or an aluminum foil. The first electrode 16 could be a metal electrode made of molybdenum (Mo), tantalum (Ta), titanium (Ti), vanadium (V) or zirconium material. The photoelectric transducing layer 18 could be a chalcopyrite structure, such as copper indium diselenide, copper indium sulfur, copper indium gallium selenide, or copper indium gallium selenide sulfur. The second electrode 20 could be made of aluminum-doped zinc oxide (AZO) material or indium tin oxide (ITO) material. The auxiliary electrode 26 could be conductive silver paste or conductive aluminum paste. The buffer layer 22 could be made of zinc sulphide (ZnS) material, cadmium sulfide (CdS), indium (II) sulfide (InS) and intrinsic zinc oxide (ZnO) material. Because dimensions of the insulating layer 24 and the auxiliary electrode 26 are designed accurately, the insulating layer 24 and the auxiliary electrode 26 could be formed on a specific area by a jet printing method for manufacturing specific shapes and dimensions, so as to set the plurality of solar batteries 101 in the series connection efficiently. Material of the substrate 14, the first electrode 16, the photoelectric transducing layer 18, the second electrode 20 and the buffer layer 22 are not limited to the above-mentioned embodiment, and depend on design demand.

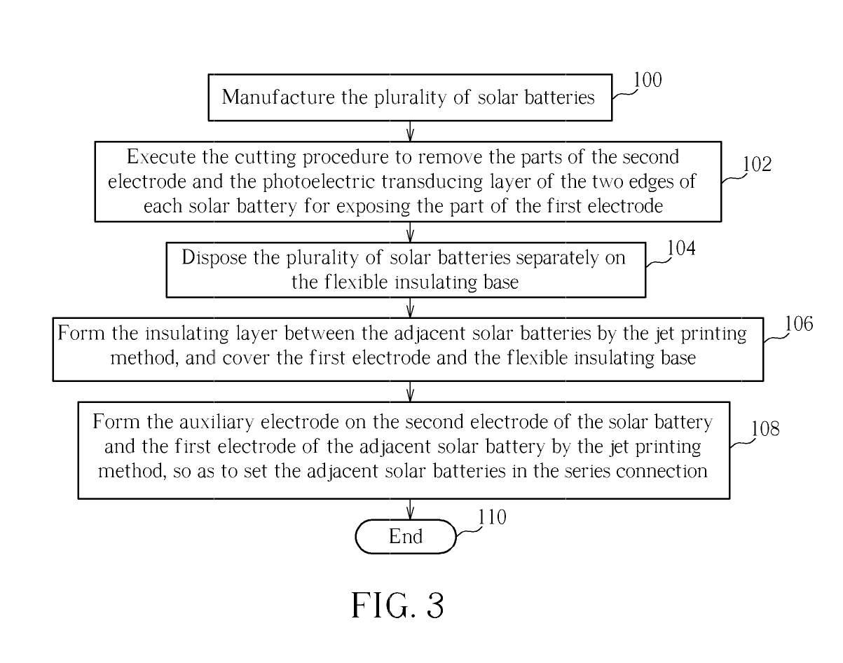

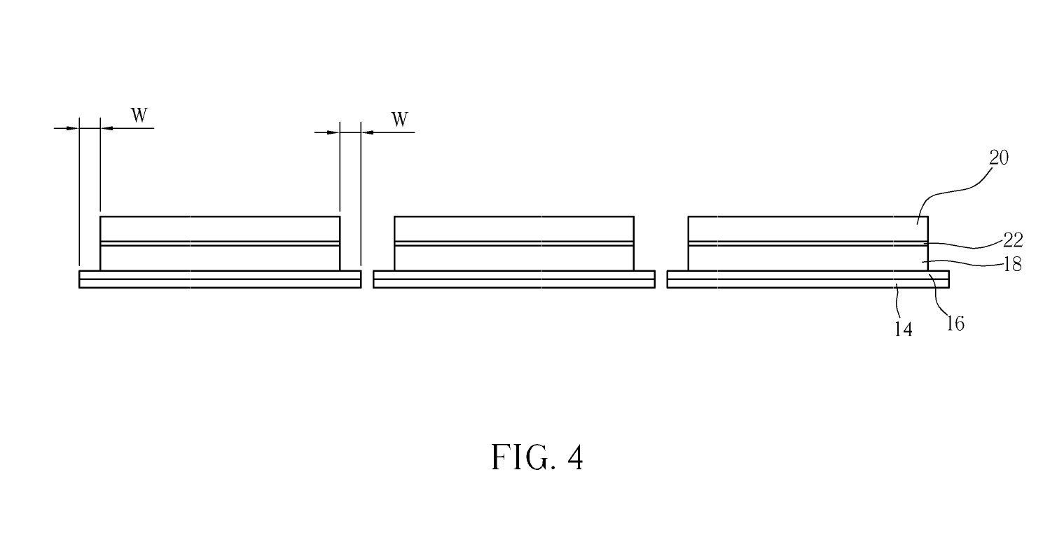

Please refer to FIG. 3 to FIG. 7. FIG. 3 is a flow chart of a method of manufacturing the flexible solar battery module 10 according to the embodiment of the present invention. FIG. 4 to FIG. 7 are sectional views of the flexible solar battery module 10 in different procedures according to the embodiment of the present invention. The method includes following steps:

Step 100: Manufacture the plurality of solar batteries 101.

Step 102: Execute the cutting procedure to remove the parts of the second electrode 20 and the photoelectric transducing layer 18 of the two edges of each solar battery 101 for exposing the part of the first electrode 16 with the width W.

Step 104: Dispose the plurality of solar batteries 101, which is manufactured by the cutting procedure, separately on the flexible insulating base 12, and the distance between the adjacent solar batteries 101 is X.

Step 106: Form the insulating layer 24 between the adjacent solar batteries 101 by the jet printing method, and cover the part of the first electrode 16 with the width W and the part of the flexible insulating base 12 with the distance X completely.

Step 108: Form the plurality of first parts 261 of each auxiliary electrode 26 respectively on the insulating layer 24 and the second electrode 20 of the corresponding solar battery 101, and form the second part 262 of each auxiliary electrode 26 on the first electrode 16 of the adjacent solar battery 101 by the jet printing method, so as to set the adjacent solar batteries 101 in the series connection.

Step 110: End.

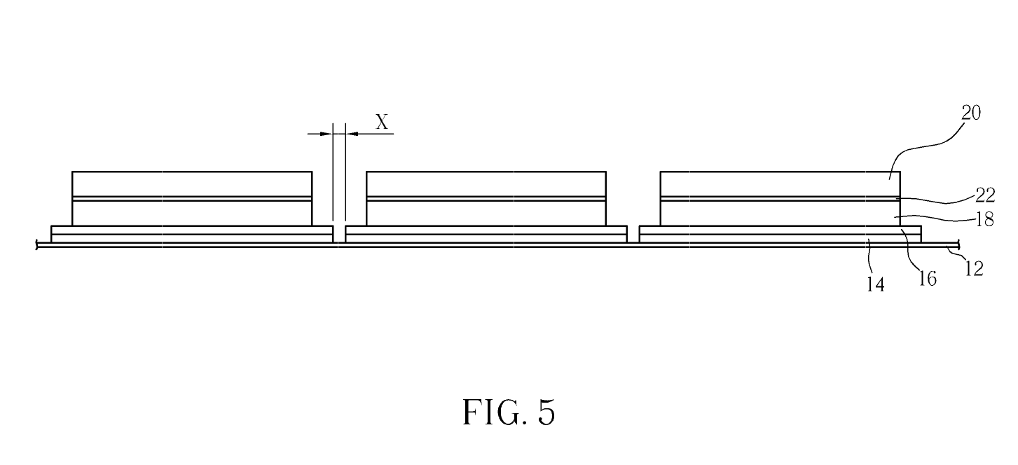

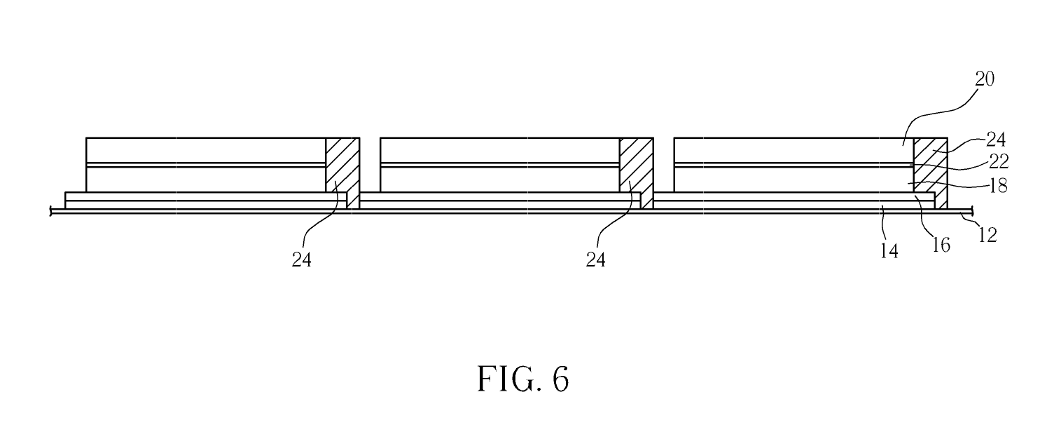

Detailed description of the method is introduced as follows. Step 100 to step 108 respectively correspond to FIG. 4 to FIG. 7. First, the plurality of solar batteries 101 could be manufactured by conventional procedures, and then execute the cutting procedure to remove the parts of the second electrode 20 and the photoelectric transducing layer 18 on the two edges of each solar battery 101, as shown in FIG. 4. The width of the exposed first electrode 16 is W due to removing the parts of the second electrode 20 and the photoelectric transducing layer 18. As shown in FIG. 5, the plurality of solar batteries 101 manufactured by the cutting procedure could be disposed on the flexible insulating base 12 separately, and the distance between the substrates 14 of the adjacent solar batteries 101 is X. The insulating layer 24 could be formed on the part of the exposed first electrode 16 of one edge between the adjacent solar batteries 101, and on the part of the exposed flexible insulating base 12 with distance X adjacent to the edge by the jet printing method, as shown in FIG. 6. The first electrode 16 and the second electrode 20 of the different solar batteries 101 could be isolated by the insulating layer 24 for preventing the flexible solar battery module 10 from the short.

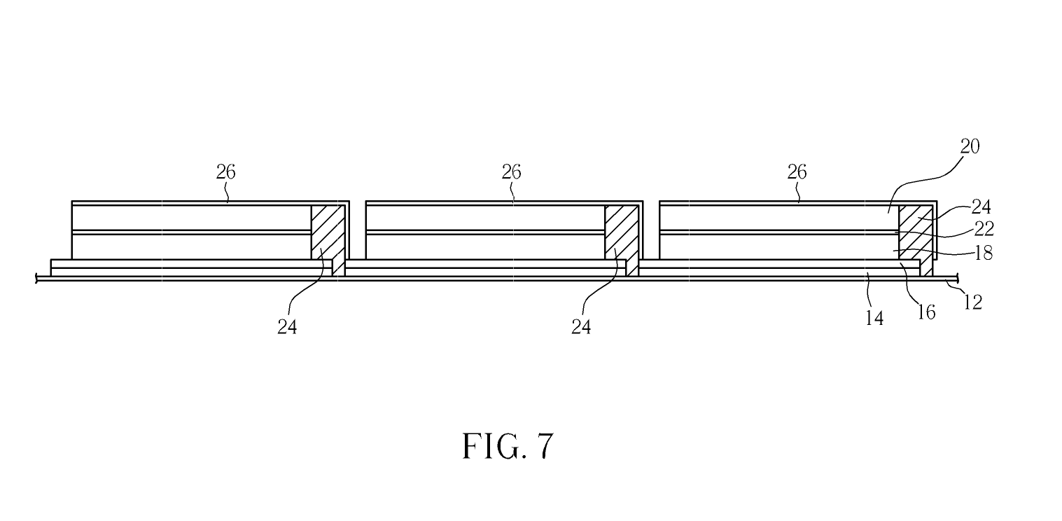

Final, as shown in FIG. 2 and FIG. 7, each auxiliary electrode 26 could be further formed across the corresponding insulating layer 24 by the jet printing method, so that two ends of the auxiliary electrode 26 could respectively contact the second electrode 20 of the corresponding solar battery 101 and the first electrode 16 of the adjacent solar battery 101. The plurality of first parts 261 of the auxiliary electrode 26 could respectively stretch on the second electrode 20 of the corresponding solar battery 101, and the second part 262 of the auxiliary electrode 26 could be formed across the insulating layer 24 to connect to the exposed first electrode 16 of the adjacent solar battery 101, so as to set the plurality of solar batteries 101 in the series connection 101. It should be mentioned that the width W2 of the second part 262 of the auxiliary electrode 26 could be smaller than the width W of the exposed first electrode 16 of the solar battery 101, and the second part 262 does not contact the second electrode 20 of the adjacent solar battery 101, so as to ensure that the adjacent solar batteries 101 are open.

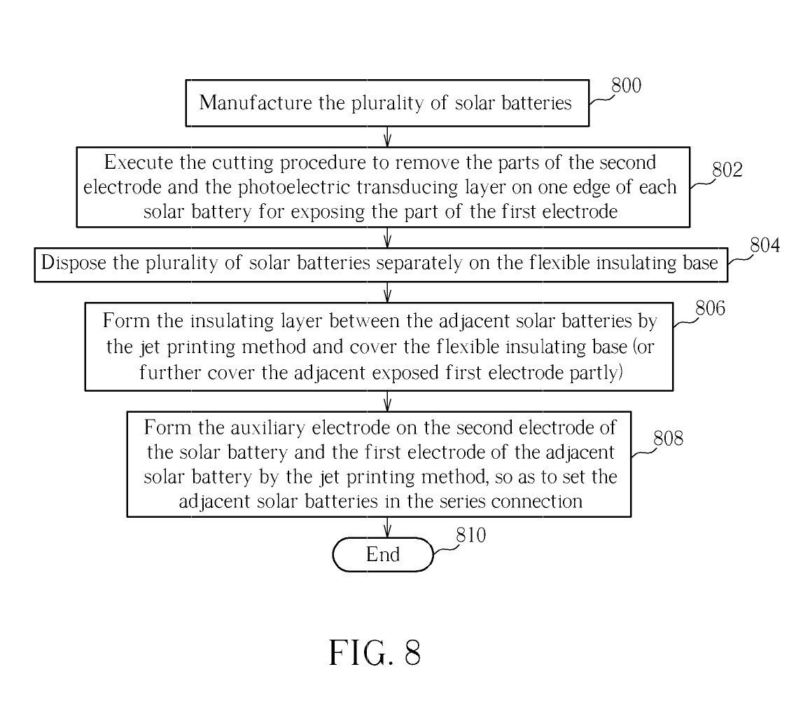

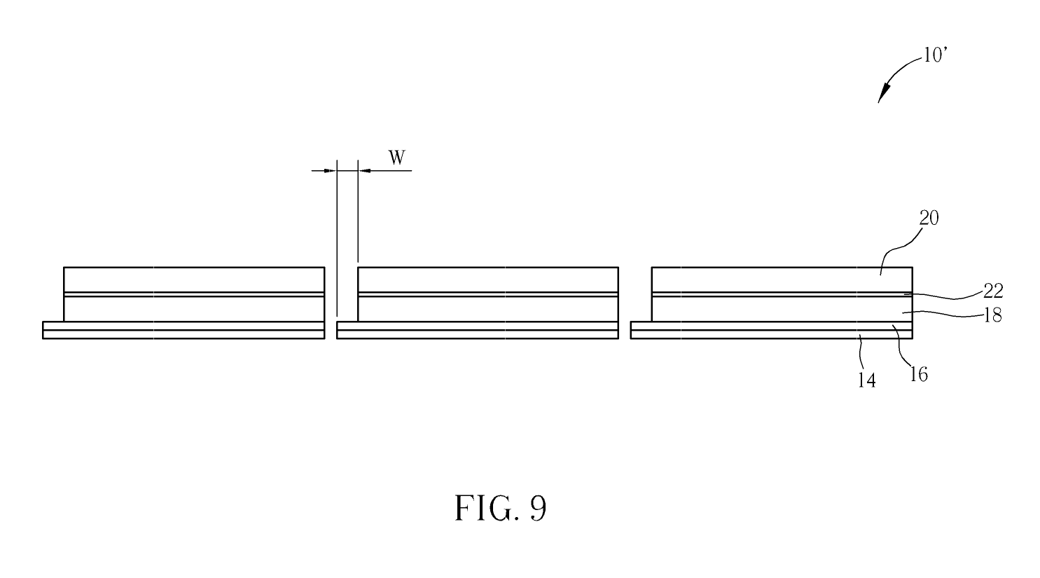

Please refer to FIG. 8 to FIG. 11. FIG. 8 is a flow chart of a method of manufacturing the flexible solar battery module 10′ according to the other embodiment of the present invention. FIG. 9 to FIG. 11 are sectional views of the flexible solar battery module 10′ in different procedures according to the other embodiment of the present invention. The method includes following steps:

Step 800: Manufacture the plurality of solar batteries 101′.

Step 802: Execute the cutting procedure to remove the parts of the second electrode 20 and the photoelectric transducing layer 18 on one of the edges of each solar battery 101′ for exposing the part of the first electrode 16 with the width W.

Step 804: Dispose the plurality of solar batteries 101′, which is manufactured by the cutting procedure, separately on the flexible insulating base 12, and the distance between the adjacent solar batteries 101′ is X.

Step 806: Form the insulating layer 24 between the adjacent solar batteries 101′ by the jet printing method, and cover the part of the first electrode 16 with the width W and the part of the flexible insulating base 12 with the distance X (or further cover the adjacent exposed first electrode 16 partly).

Step 808: Form the plurality of first parts 261 of each auxiliary electrode 26 respectively on the insulating layer 24 and the second electrode 20 of the corresponding solar battery 101′, and form the second part 262 of each auxiliary electrode 26 on the first electrode 16 of the adjacent solar battery 101′ by the jet printing method, so as to set the adjacent solar batteries 101′ in the series connection.

Step 810: End.

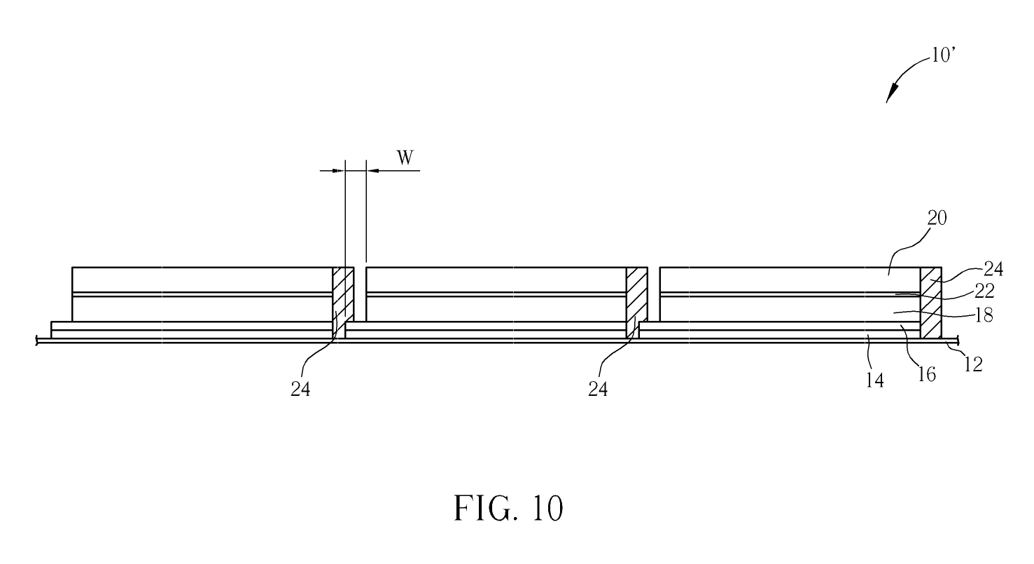

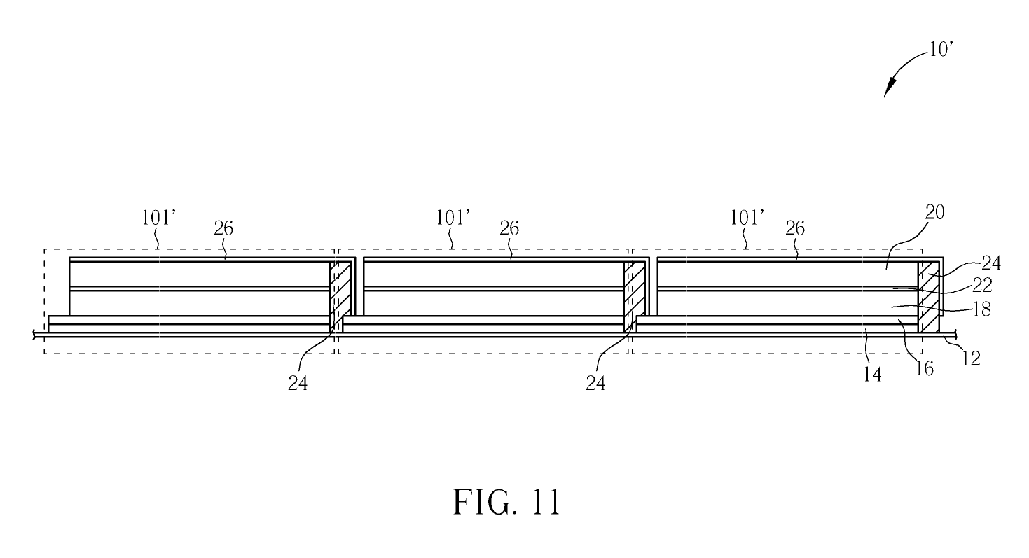

Detailed description of the method is introduced as follows. As shown in FIG. 9 (step 800 and step 802), the plurality of solar batteries 101′ could be manufactured by the conventional procedures, and then execute the single-side cutting procedure to remove the parts of the second electrode 20 and the photoelectric transducing layer 18 on the edge of each solar battery 101′. As shown in FIG. 10 (step 804 and step 806), the plurality of solar batteries 101′ manufactured by the single-side cutting procedure could be disposed on the flexible insulating base 12 separately, and the distance between the adjacent solar batteries 101′ is X. Then, each insulating layer 24 could be formed on the exposed flexible insulating base 12 with the distance X between the adjacent solar batteries 101′ by the jet printing method (or the insulating layer 24 could further cover the exposed first electrode 16 of the adjacent solar battery 101′ partly). As shown in FIG. 11 (step 808), the ends of each auxiliary electrode 26 could be respectively formed on the second electrode 20 of the corresponding solar battery 101′ and the first electrode 16 of the adjacent solar battery 101′ by the jet printing method, so as set the plurality of solar batteries 101′ in the series connection.

Difference between the embodiment (the plurality of solar batteries 101′) and the above-mentioned embodiment (the plurality of solar batteries 101) is that the solar battery 101′ is manufactured by the single-side cutting procedure, such as step 802. The insulating layer 24 could selectively be formed on the part of the flexible insulating base 12 with the distance X, or be formed on the part of the flexible insulating base 12 with the distance X and the adjacent exposed first electrode 16 when forming the insulating layer 24 between the adjacent solar batteries 101′ in step 806, so as to effectively prevent the adjacent solar batteries 101′ from the short. In this embodiment, elements having the same numerals as ones of the above-mentioned embodiment have the same structures and functions, and detail description is omitted herein for simplicity.

In conclusion, the flexible solar battery module of the present invention could dispose the plurality of independent solar batteries on the flexible insulating base, and the first electrode of each solar battery could be exposed by the cutting procedure for the latter series connection. The plurality of solar batteries could be separately disposed on the flexible insulating base, and the insulating layer could be formed between the adjacent solar batteries by the jet printing method for preventing the short. Final, the ends of the auxiliary electrode could be respectively connected to the first electrode and the second electrode of the adjacent solar batteries (which means a positive electrode and a negative electrode of the adjacent solar batteries) by the jet printing method, so as to set the plurality of solar batteries in the series connection.

Comparing to the prior art, the present invention could dispose the plurality of solar batteries separately on the flexible insulating base, and form the insulating layer between the adjacent solar batteries for preventing the short. The present invention could further utilize the auxiliary electrode to connect the adjacent solar batteries for forming the flexible solar battery module. In addition, the present invention has advantages of easy manufacturing procedures, so that the present invention could manufacture the flexible solar battery module with preferable manufacturing quality and preferred photoelectric transducing efficiency.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of setting a plurality of solar batteries in a series connection to be a flexible solar battery module, the solar battery comprising a substrate, a first electrode, a photoelectric transducing layer and a second electrode, the method comprising:
executing a cutting procedure to the plurality of solar batteries, so as to remove parts of the second electrode and the photoelectric transducing layer of at least one edge of each solar battery for exposing a part of the first electrode;
disposing the plurality of solar batteries separately on a flexible insulating base to expose a part of the flexible insulating base;
forming an insulating layer between the adjacent solar batteries and on the part of the flexible insulating base; and
forming an auxiliary electrode on the second electrode of each solar battery and the part of the exposed first electrode of the adjacent solar battery for setting the plurality of solar batteries in the series connection.

2. The method of claim 1, further comprising:
removing parts of the second electrode and the photoelectric transducing layer of two edges of each solar battery for exposing the part of the first electrode.

3. The method of claim 2, further comprising:
forming the insulating layer on the part of the exposed first electrode of the edge of each solar battery and on the part of the flexible insulating base between the adjacent solar batteries.

4. The method of claim 1, further comprising:
forming a plurality of first parts of the auxiliary electrode respectively on the insulating layer and the second electrode of the solar battery; and
forming a second part of the auxiliary electrode on the first electrode of the adjacent solar battery, wherein an end of each first part is connected to the second part for forming a bus bar structure.

5. The method of claim 4, wherein a width of the second part of the auxiliary electrode is smaller than a width of the part of the exposed first electrode of each solar battery.

6. The method of claim 1, further comprising:
utilizing the insulating layer to isolate the first electrode and the second electrode of each solar battery from the first electrode of the adjacent solar battery.

7. The method of claim 1, further comprising:
forming the auxiliary electrode across the insulating layer, two ends of the auxiliary electrode respectively contacting the second electrode of each solar battery and the first electrode of the adjacent solar battery.

8. The method of claim 1, further comprising:
forming the insulating layer between the adjacent solar batteries by a jet printing method.

9. The method of claim 1, further comprising:
forming the auxiliary electrode on the second electrode of each solar battery and the part of the exposed first electrode of the adjacent solar battery by a jet printing method.

10. A flexible solar battery module comprising:
a flexible insulating base;
a plurality of solar batteries separately disposed on the flexible insulating base, each solar battery comprises:
a substrate disposed on the flexible insulating base;
a first electrode formed on the substrate;
a photoelectric transducing layer formed on a surface of the first electrode for exposing a part of the first electrode, and a width of the photoelectric transducing layer being smaller than a width of the first electrode; and
a second electrode formed on the photoelectric transducing layer;
an insulating layer formed on the part of the exposed first electrode of each solar battery and the part of the exposed flexible insulating base of the adjacent solar battery; and
an auxiliary electrode formed on the second electrode of each solar battery and the part of the exposed first electrode of the adjacent solar battery for setting the plurality of solar batteries in a series connection.

11. The flexible solar battery module of claim 10, wherein the auxiliary electrode comprises a plurality of first parts and a second part, an end of each first part is connected to the second part for forming a bus bar structure, the plurality of first parts is respectively disposed on the insulating layer and the second electrode of the solar battery, and the second part is disposed on the first electrode of the adjacent solar battery.

12. The flexible solar battery module of claim 11, wherein a width of the second part of the auxiliary electrode is smaller than a width of the part of the exposed first electrode of each solar battery.

13. The flexible solar battery module of claim 10, wherein the first electrode and the second electrode of each solar battery is isolated from the first electrode of the adjacent solar battery by the insulating layer.

14. The flexible solar battery module of claim 10, wherein the auxiliary electrode is formed across the insulating layer, so that two ends of the auxiliary electrode respectively contact the second electrode of each solar battery and the first electrode of the adjacent solar battery.

15. The flexible solar battery module of claim 10, wherein the solar battery further comprises:
a buffer layer formed between the photoelectric transducing layer and the second electrode.

16. The flexible solar battery module of claim 10, wherein the first electrode is made of metal material.

17. The flexible solar battery module of claim 10, wherein the photoelectric transducing layer is a chalcopyrite structure.

18. The flexible solar battery module of claim 10, wherein the second electrode is made of aluminum-doped zinc oxide material or indium tin oxide material.

19. The flexible solar battery module of claim 10, wherein the insulating layer and the auxiliary electrode are formed by a jet printing method.

20. The flexible solar battery module of claim 10, wherein the substrate is a metal foil.
